(19) United States
(12) Patent Application Publication
(10) Pub. No.: US 2025/0393271 A1
(43) Pub. Date: Dec. 25, 2025

(54) ASYMMETRICAL BACKSIDE CONTACT FOR SHIFTED STACKED TRANSISTOR

(71) Applicant: International Business Machines Corporation, Armonk, NY (US)

(72) Inventors: Ruilong Xie, Niskayuna, NY (US); Shay Reboh, Guilderland, NY (US); Nicholas Anthony Lanzillo, Wynantskill, NY (US); James P Mazza, Saratoga Springs, NY (US); Chen Zhang, Santa Clara, CA (US)

(21) Appl. No.: 18/752,207

(22) Filed: Jun. 24, 2024

(51) Int. Cl. H01L 29/08; H01L 23/528; H01L 27/092; H01L 29/06; H01L 29/423; H01L 29/775; H01L 29/786

(52) U.S. Cl. CPC H10D 62/151; H01L 23/5286; H10D 30/43; H10D 62/121; H10D 84/853; H10D 30/6735; H10D 30/6757

(57) ABSTRACT

A semiconductor device is provided that includes a top transistor located in a top active device area and stacked over a bottom transistor located in a bottom active device area in which the top active device area is shifted relative to the bottom active device area and in which the top transistor and the bottom transistor are electrically connected to a backside BEOL structure. Asymmetrical bottom device backside source/drain contact structures are used in electrically connecting the backside BEOL structure to a bottom device source/drain region of the bottom transistor.

### BACKGROUND

The present application relates to semiconductor technology, and more particularly to a semiconductor device including one transistor stacked over another transistor in which the top active device area is shifted relative to the bottom active device area and in which both transistors are electrically connected to a backside back-end-of-the-line (BEOL) structure.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance). Also, placing the power lines on the backside can reduce interference with signal paths and minimize heat buildup near the active device regions.

### SUMMARY

A semiconductor device is provided that includes a top transistor located in a top active device area and stacked over a bottom transistor located in a bottom active device area in which the top active device area is shifted relative to the bottom active device area and in which the top transistor and the bottom transistor are electrically connected to a backside BEOL structure. In the present application, asymmetrical bottom device backside source/drain contact structures are used in electrically connecting the backside BEOL structure to a bottom device source/drain region of the bottom transistor.

In one embodiment of the present application, the semiconductor device incudes a bottom transistor including a bottom device gate structure and bottom device source/drain regions located in a bottom active device area, a top transistor stacked above the bottom transistor and including a top device gate structure and top device source/drain regions located in a top active device area, in which the top active device area is shifted relative to the bottom active device area, a backside BEOL structure located beneath the bottom transistor, an asymmetrical bottom device backside source/drain contact structure electrically connecting a first bottom device source/drain region of the bottom device source/drain regions to the backside BEOL structure, and a top device backside source/drain contact structure electrically connecting a first top device source/drain region of the top device source/drain regions to the backside BEOL structure.

In another embodiment of the present application, the semiconductor device includes a bottom transistor including a bottom device gate structure and bottom device source/drain regions located in a bottom active device area, a top transistor stacked above the bottom transistor and including a top device gate structure and top device source/drain regions located in a top active device area, in which the top active device area is shifted relative to the bottom active device area, a backside BEOL structure located beneath the bottom transistor, an asymmetrical bottom device backside source/drain contact structure having a horizontal portion contacting an entirety of a bottommost surface of a first bottom device source/drain region of the bottom device source/drain regions and a vertical portion contacting the backside BEOL structure, and a top device backside source/drain contact structure electrically connecting a first top device source/drain region of the top device source/drain regions to the backside BEOL structure.

### BRIEF DESCRIPTION OF THE DRAWINGS

FIG. 1 is a top down view of a device layout that can be employed in accordance with an embodiment of the present application.

FIGS. 2A-2C are cross sectional views of an exemplary structure through cuts A-A, B-B and C-C, respectively, of FIG. 1 that can be used in accordance with an embodiment of the present application, the exemplary structure including at least one bottom transistor including a bottom device gate structure and bottom device source/drain regions and located on a surface of a substrate, a bottom device backside source/drain contact placeholder structure located beneath each bottom device source/drain region, and a bottom device frontside interlayer dielectric (ILD) layer embedding the bottom device source/drain regions.

FIGS. 3A-3C are cross sectional views of the exemplary structure of FIGS. 2A-2C, respectively, after forming top device source/drain contact placeholder structures in the bottom device frontside ILD layer and through a trench dielectric material of a shallow trench isolation structure, each top device source/drain contact placeholder structure landing on a trench dielectric liner of the shallow trench isolation structure.

FIGS. 4A-4C are cross sectional views of the exemplary structure of FIGS. 3A-3C, respectively, after bonding a top device material stack of alternating top device sacrificial semiconductor material layers and top device semiconductor channel material layers above the at least one bottom transistor and on the bottom device frontside ILD layer.

FIGS. 5A-5C are cross sectional views of the exemplary structure of FIGS. 4A-4C, respectively, after forming a top transistor-containing structure including at least one top transistor including a top device gate structure and top device source/drain regions, and a top device first frontside ILD layer embedding the top device source/drain regions, wherein some of the top device source/drain regions are formed in contact with an underlying top device source/drain contact placeholder structure.

FIGS. 6A-6C are cross sectional views of the exemplary structure of FIGS. 5A-5C, respectively, after forming a middle-of-the-line (MOL) level, a frontside BEOL structure and a carrier wafer.

FIGS. 7A-7C are cross sectional views of the exemplary structure of FIGS. 6A-6C, respectively, after wafer flipping and removing a semiconductor base layer of the substrate.

FIGS. 8A-8C are cross sectional views of the exemplary structure of FIGS. 7A-7C, respectively, after removing an etch stop layer and a semiconductor device layer of the substrate to reveal the bottom device backside source/drain contact placeholder structures and the trench dielectric liner of the shallow trench isolation structure.

FIGS. 9A-9C are cross sectional views of the exemplary structure of FIGS. 8A-8C, respectively, after forming a first backside ILD layer contacting the trench dielectric liner and embedding the bottom device backside source/drain contact placeholder structures.

FIGS. 10A-10C are cross sectional views of the exemplary structure of FIGS. 9A-9C, respectively, after replacing the bottom device backside source/drain contact placeholder structures with bottom device backside source/drain contact structures.

FIGS. 11A-11C are cross sectional views of the exemplary structure of FIGS. 10A-10C, respectively, after asymmetric backside contact patterning in which the bottom device backside source/drain contact structures are patterned into asymmetrical bottom device backside source/drain contact structures.

FIGS. 12A-12C are cross sectional views of the exemplary structure of FIGS. 11A-11C, respectively, after forming a second backside ILD layer.

FIGS. 13A-13C are cross sectional views of the exemplary structure of FIGS. 12A-12C, respectively, after VDD backside power rail patterning in which the top device source/drain contact placeholder structures are revealed.

FIGS. 14A-14C are cross sectional views of the exemplary structure of FIGS. 13A-13C, respectively, after removing the top device source/drain contact placeholder structures.

FIGS. 15A-15C are cross sectional views of the exemplary structure of FIGS. 14A-14C, respectively, after forming top device backside source/drain contact structures.

FIGS. 16A-16C are cross sectional views of the exemplary structure of FIGS. 15A-15C, respectively, after VSS backside power rail patterning and VDD/VSS backside power rail metallization.

FIGS. 17A-17C are cross sectional views of the exemplary structure of FIGS. 16A-16C, respectively, after forming a backside BEOL structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the present application, a stacked transistor in which one transistor (i.e., a top transistor) is stacked over another transistor (i.e., a bottom transistor) is disclosed. In the embodiment described in the present application, the stacked transistor includes a top nanosheet transistor stacked over a bottom nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although a stacked nanosheet transistor is described in this application, this application is not limited to stacked nanosheet transistors. Instead, the present application can be used for stacked finFETs, stacked nanowire FETs, stacked planar FETs, stacked fork sheet transistors, or any combination of such FETs including nanosheet transistors.

In the present application, the semiconductor device includes a frontside and a backside. The frontside includes a side of the device that includes at least one stacked transistor, frontside contact structures, and a frontside BEOL structure. The backside of the semiconductor device is the side of the device that is opposite the frontside. The backside includes backside contact structures, and a backside BEOL structure. The backside BEOL structure can be a backside power distribution network that is capable of delivering power to the transistor through the backside of the semiconductor device.

In the present application, the top transistor is located in a top active device area that is shifted relative to a bottom active device region into the bottom transistor. The shifted configuration allows for easier contact formation of a top device source/drain region to a backside BEOL structure, and of a bottom device source/drain region to a frontside BEOL structure.

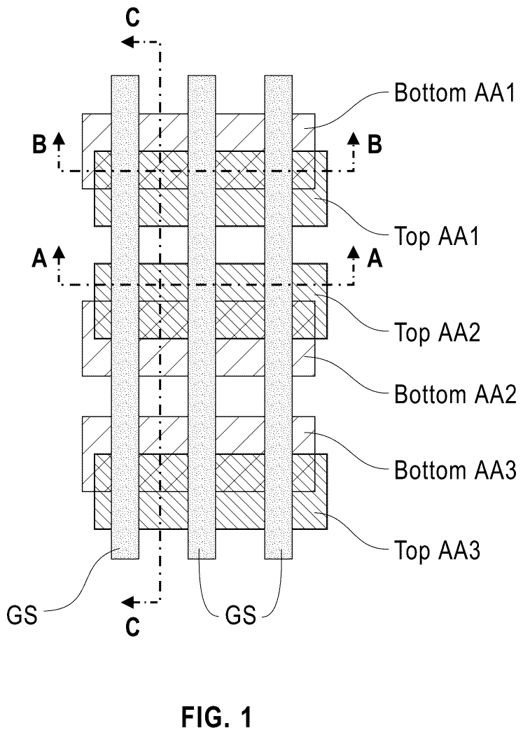

Referring first to FIG. 1, there is illustrated a device layout that can be employed in accordance with an embodiment of the present application. The illustrated device layout of FIG. 1 includes three stacked transistor regions, namely a first stacked transistor region including a bottom first active device area (i.e., bottom AA1) and a top first active device area (i.e., top AA1), a second stacked transistor region including a bottom second active device area (i.e., bottom AA2) and a top second active device area (i.e., top AA2), and a third stacked transistor region including a bottom third active device area (i.e., bottom AA3) and a top third active device area (i.e., top AA3). In the illustrated device layout, each top active device area is stacked over a respective bottom active device region, and each top active device area is shifted (i.e., staggered) relative to the respect bottom active device area. The shift between the upper and bottom active device areas is best seen in cut C-C. The device layout illustrated in FIG. 1 shows three gate structures (each gate structure is labeled as GS) that lie parallel to each other and perpendicular to each of the stacked transistor regions. Three gate structures are shown by way of one example. The present application is not limited to using three gate structures. The gate structures represent the location in which the top device gate structures are present. Although three stacked transistor regions are shown in the device layout of FIG. 1, the present application works when at least one stacked transistor region is present.

FIG. 1 also includes three different cuts, namely cut A-A, cut B-B, and cut C-C that will be used throughout the remaining drawings of the present application. Cut A-A is a cut that runs in a length wise direction through a portion of the second stacked transistor region including bottom AA2 and top AA2. Cut B-B is a cut that runs in a length wise direction through a portion of the first stacked transistor region including bottom AA1 and top AA1. Cut C-C is a cut that runs in a direction (perpendicular to cuts A-A and B-B) between the first gate structure and the second gate structure (referenced from the left hand side of the drawing to the right hand side of the drawing) and it passes through each of the first stacked transistor region, the second stacked transistor region and the third stacked transistor region. Notably, cut C-C will show the source/drain areas (including a bottom device source/drain area and a top device source/drain area) of the each of stacked transistors of the present application.

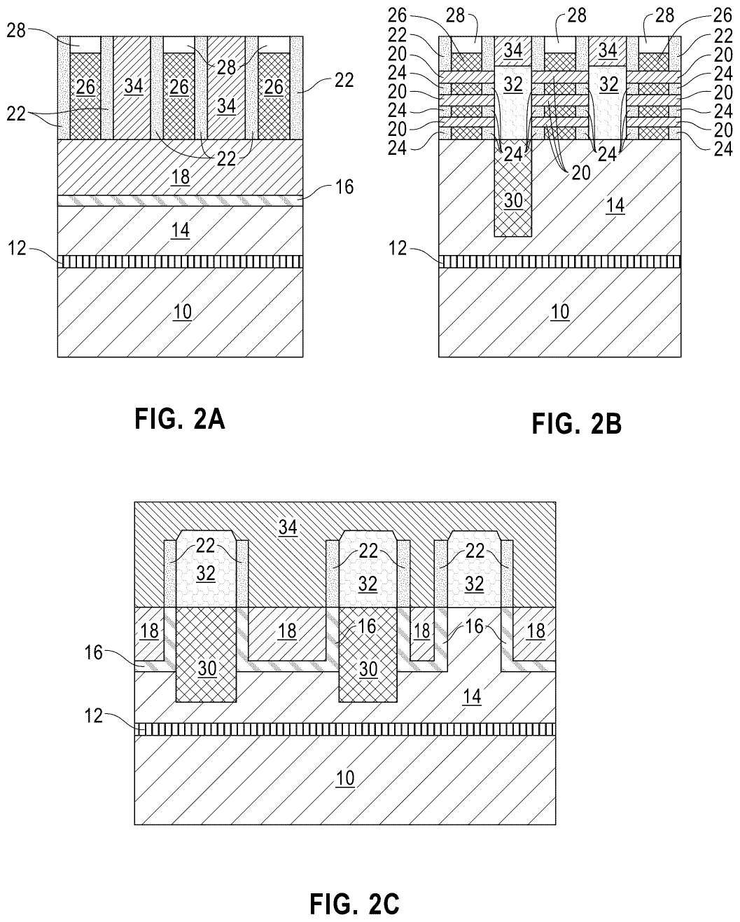

Referring now to FIGS. 2A-2C, there are illustrated an exemplary structure through cuts A-A, B-B and C-C, respectively, of FIG. 1 that can be used in accordance with an embodiment of the present application, the exemplary structure including at least one bottom transistor including a bottom device gate structure 26 and bottom device source/drain regions 32 and located on a surface of a substrate, a bottom device backside source/drain contact placeholder structure 30 located beneath each bottom device source/drain region 32, and a bottom device frontside ILD layer 34 embedding the bottom device source/drain regions 32. The exemplary structure illustrated in FIGS. 2A-2C can also include a bottom device vertical nanosheet stack of spaced apart bottom device semiconductor channel material nanosheets 20 (three bottom device vertical nanosheet stacks are illustrated in the drawings), shallow trench isolation structures including a dielectric trench liner 16 and a trench dielectric material 18 that are located between the different bottom active device areas, bottom device gate spacers 22 located adjacent to the bottom device gate structure 26 and the bottom device source/drain regions 32, bottom device inner spacers 24 that are located beneath, and at the ends of, each of the bottom device semiconductor channel material nanosheets 20 in a given bottom device vertical nanosheet stack, and bottom device sacrificial gate cap 28 located on top of each bottom device gate structure 26. Each bottom device vertical nanosheet stack represents a bottom device semiconductor channel region of a bottom nanosheet transistor. Each of the elements illustrated in FIGS. 2A-2C will now be described in greater detail.

The substrate includes at least a semiconductor device layer 14. In addition to the semiconductor device layer 14, the substrate can also include a semiconductor base layer 10 and/or an etch stop layer 12. Embodiments are contemplated in which the semiconductor base layer 10 and/or the etch stop layer 12 are omitted and the substrate includes only the semiconductor device layer 14. The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

Each shallow trench isolation structure is located in an upper portion of the substrate and is located between the various bottom active device areas. Notably, each shallow trench isolation structure is present in the semiconductor device layer 14 of the substrate. Each shallow trench isolation structure can include trench dielectric liner 16 and trench dielectric material 18. The trench dielectric liner 16 includes a trench dielectric liner material such as, for example, silicon nitride. The trench dielectric material 18 is composed of any trench dielectric such as, for example, silicon dioxide. The trench dielectric liner 16 is present along a sidewall and a bottom wall of the trench dielectric material 18. In some embodiments, each shallow trench isolation structure can have a topmost surface that is substantially coplanar with a topmost surface of the substrate (e.g., the semiconductor device layer 14). In other embodiments, each shallow trench isolation structure can have a topmost surface that is vertically offset (i.e., higher or lower) than a topmost surface of the substrate (e.g., the semiconductor device layer 14).

Each bottom device semiconductor channel material nanosheet 20 is composed of a fourth semiconductor material. The fourth semiconductor material can be compositionally the same as, or compositionally different from, the second semiconductor material that provides the semiconductor device layer 14. In some embodiments, the fourth semiconductor material that provides each bottom device semiconductor channel material nanosheet 20 provides high channel mobility for NFET devices. In other embodiments, the fourth semiconductor material that provides each bottom device semiconductor channel material nanosheet 20 provides high channel mobility for PFET devices. In one example, each bottom device semiconductor channel material nanosheet 20 is composed of silicon.

The bottom device gate spacers 22 and the bottom device inner spacers 24 are composed of a same or different dielectric spacer material. Illustrative dielectric spacer materials that can be used for the bottom device gate spacers 22 and the bottom device inner spacers 24 include, but are not limited to, silicon dioxide, SiN, SiBCN, SiOCN or SiOC.

The bottom device gate structure 26 includes a bottom device gate dielectric material and a bottom device gate electrode, both of which are not separately shown, but intended to be within the region defined by bottom device gate structure 26. As is known to those skilled in the art, a gate dielectric material directly contacts a physically exposed surface(s) of the semiconductor channel region, and a gate electrode is formed on the gate dielectric material. The bottom device gate dielectric material has a dielectric constant of 4.0 or greater. All dielectric constants mentioned herein are measured in a vacuum, unless otherwise noted to the contrary. Illustrative examples of bottom device gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The bottom device gate dielectric material can further include dopants such as lanthanum (La), aluminum (Al) and/or magnesium (Mg). The bottom device gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

The bottom device sacrificial gate cap 28, which is present on top of each bottom device gate structure 26 and located between a bottom device gate spacer 22 that lines each bottom device gate structure 26, is composed of a dielectric hard mask material including, for example, silicon dioxide, silicon nitride and/or silicon oxynitride. The sacrificial gate cap 28 has a different dielectric composition than the bottom dielectric gate spacers 22.

Each bottom device backside source/drain contact placeholder structure 30 is composed of a fifth semiconductor material which is compositionally different from second semiconductor material that provides the semiconductor device layer 14. Each bottom device bottom device backside source/drain contact placeholder structure 30 typically has a topmost surface that is substantially coplanar with a topmost surface of the semiconductor device layer 14 and a bottommost surface that lands on a sub-surface of the semiconductor device layer 14. In the present application, the term “sub-surface” denotes a surface of a material/structure that is located between a topmost surface and a bottommost surface of the material/structure. In some embodiments (not shown), a bottom device semiconductor buffer layer can be formed on top of each bottom device backside source/drain contact placeholder structure 30 prior to forming the bottom device source/drain regions 32. When present, the bottom device semiconductor buffer layer is composed of a sixth semiconductor material which is compositionally different from the fifth semiconductor material that provides each bottom device backside source/drain contact placeholder structure 30. When present, the bottom device semiconductor buffer layer facilitates the formation of bottom source/drain regions 32. When present, each bottom device semiconductor buffer layer has a topmost surface that is below a bottommost surface of the bottommost bottom device semiconductor channel material nanosheet 20 of a given bottom device bottom device vertical nanosheet stack.

Each bottom device source/drain region 32 is located on opposing sides of a given bottom device vertical nanosheet stack. Each bottom device source/drain region 32 extends outward from a sidewall of the bottom device semiconductor channel material nanosheets 20 of a given bottom device vertical nanosheet stack. Each bottom source/drain region 32 is composed of a seventh semiconductor material and a first dopant. As used herein, a “source/drain” region can be a source region or a drain region depending on subsequent wiring and application of voltages during operation of the transistor. The seventh semiconductor material that provides the bottom device source/drain regions 32 can be compositionally the same as, or compositionally different from, the fourth semiconductor material that provides each bottom device semiconductor channel material nanosheet 20. The seventh semiconductor material that provides each bottom device source/drain region 32 is compositionally different from the fifth semiconductor material that provides each bottom device backside source/drain contact placeholder structure 30. The first dopant that is present in the bottom device source/drain regions 32 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the bottom device source/drain regions 32 can have a first dopant concentration of from 4×10²⁰ atoms/cm³ to 3×10²¹ atoms/cm³. At this point of the present application, each bottom device source/drain region 32 has a same critical dimension (i.e., width) as the underlying bottom device backside source/drain contact placeholder structure 30.

The bottom device frontside ILD layer 34 is composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

The exemplary structure shown in FIGS. 2A-2C can be formed utilizing any well-known nanosheet transistor device fabrication process in which backside source/drain contact placeholder structures are formed into a substrate prior to forming the source/drain regions. The nanosheet transistor device fabrication process typically includes the use of a sacrificial gate structure which is used in defining a nanosheet stack of alternating sacrificial semiconductor nanosheets and semiconductor channel material nanosheets. After defining the nanosheet stack, the sacrificial gate structure is removed to reveal the underlying nanosheet stack and thereafter each sacrificial semiconductor material nanosheet of the nanosheet stack is removed and thereafter a gate structure is formed wrapping around each of the suspended semiconductor channel material nanosheets of the nanosheet stack, the gate structure is then recessed and a sacrificial gate cap is formed.

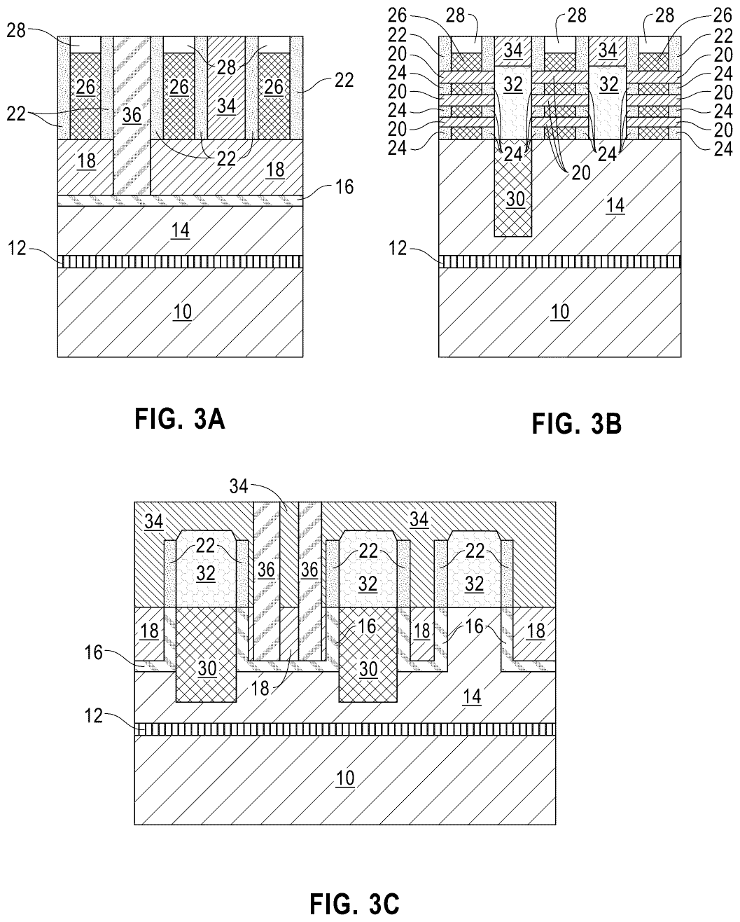

Referring now to FIGS. 3A-3C, there are illustrated the exemplary structure of FIGS. 2A-2C, respectively, after forming top device source/drain contact placeholder structures 36 in the bottom device frontside ILD layer 34 and through the trench dielectric material 18 of a shallow trench isolation structure, each top device source/drain contact placeholder structure 36 lands on trench dielectric liner 16 of the shallow trench isolation structure. The top device source/drain contact placeholder structures 36 are formed between a neighboring pair of bottom device gate structure 26 as shown in FIG. 3A and between a neighboring pair of bottom device source/drain regions 32 as shown in FIG. 3C. In the present application, two top device source/drain contact placeholder structures 36 are formed between a neighboring pair of bottom device source/drain regions 32 as shown in FIG. 3C; this accommodates for the subsequent formation of top devices having a shift in the top active device area. The top device source/drain contact placeholder structures 36 are composed of a sacrificial placeholder material that is compositionally different from the dielectric material that provides the bottom device frontside ILD layer 34. Illustrative examples of sacrificial placeholder materials that can be used in providing the top device source/drain contact placeholder structures 36 include, but are not limited to, titanium nitride, titanium dioxide and aluminum oxide.

The top device source/drain contact placeholder structures 36 can be formed by first forming top device source/drain contact placeholder structure openings in the bottom device frontside ILD layer 34 that extend through the trench dielectric material 18 and stop of the trench dielectric liner 16 of a shallow trench isolation structure. The top device source/drain contact placeholder structure openings can be formed by lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. After forming the top device source/drain contact placeholder structure openings, the top device source/drain contact placeholder structure openings are filled with a sacrificial placeholder material as defined above. The filling of the top device source/drain contact placeholder structure openings includes deposition of the sacrificial placeholder material, followed by a planarization process such as, for example, chemical mechanical polishing (CMP). The deposition of the sacrificial placeholder material includes chemical vapor deposition (CVD), plasma enhanced chemical vapor deposition (PECVD), physical vapor deposition (PVD) or atomic layer deposition (ALD). After planarization of the as deposited sacrificial placeholder material, the as deposited sacrificial placeholder material that remains in each of the top device source/drain contact placeholder structure openings provides the top device source/drain contact placeholder structure 36 of the present application. Each top device source/drain contact placeholder structure 36 has a topmost surface that is substantially coplanar with a topmost surface of the bottom device frontside ILD layer 34.

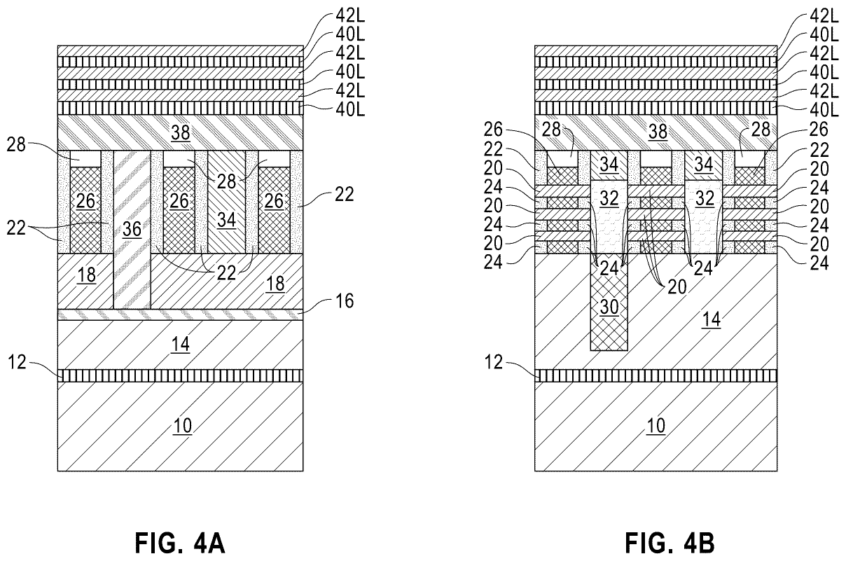

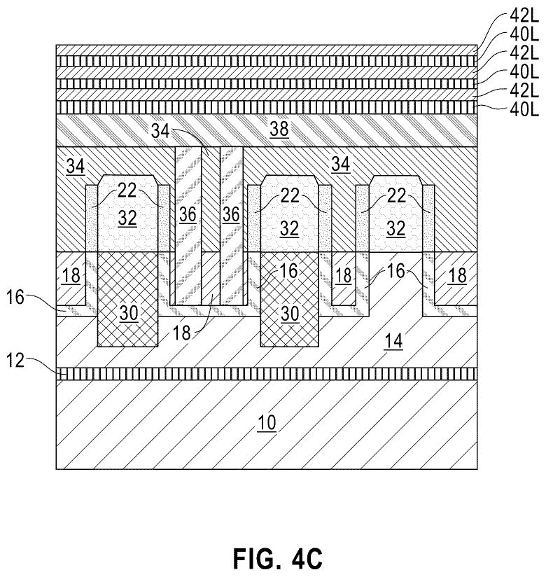

Referring now to FIGS. 4A-4C, there are illustrated the exemplary structure of FIGS. 3A-3C, respectively, after bonding a top device material stack of alternating top device sacrificial semiconductor material layers 40L and top device semiconductor channel material layers 42L above the at least one bottom transistor and on the bottom device frontside ILD layer 34. Each sacrificial semiconductor material layer 40L of the top device material stack is composed of an eighth semiconductor material, while each top device semiconductor channel material layer 42L is composed of a ninth semiconductor material which is compositionally different from the eighth semiconductor material. The ninth semiconductor material that provides each top device semiconductor channel material layer 42L can be compositionally the same as, or compositionally different from, the fourth semiconductor material that provides each bottom device semiconductor channel material nanosheet 20. In some embodiments, the ninth semiconductor material that provides each top device semiconductor channel material layer 42L provides high channel mobility for NFET devices. In other embodiments, the ninth semiconductor material that provides each top device semiconductor channel material layer 42L provides high channel mobility for PFET devices. The top device material stack can be formed utilizing a deposition process or a combination of deposition processes can be used. Exemplary deposition process(es) that can be used include, for example, CVD, PECVD and/or epitaxial growth.

The bonding of the top device material stack of alternating top device sacrificial semiconductor material layers 40L and top device semiconductor channel material layers 42L includes the use of a bonding dielectric layer 38 as shown in FIGS. 4A-4C. In the present application, the bonding dielectric layer 38 is composed of any bonding dielectric material such as, for example, tetraethyl orthosilicate (TEOS), silicon dioxide (SiO₂), silicon carbon nitride (SiCN) and/or carbon-doped silicon oxide (SiCOH). The bonding dielectric material that provides the bonding dielectric layer 38 can be formed by a deposition process such as, for example, CVD, PECVD, ALD, or PVD. In some embodiments, the bonding dielectric layer 38 is formed on only the exemplary structure shown in FIGS. 3A-3C prior to bonding it to the top device material stack. In other embodiments, the bonding dielectric layer 38 is formed on only the top device material stack prior to bonding it to the exemplary structure shown in FIGS. 3A-3C. In yet other embodiments, a first portion of the bonding dielectric layer 38 is formed on the exemplary structure shown in FIGS. 3A-3C and a second portion of the bonding dielectric layer 38 is formed on the top device material stack, and these two portions of the bonding dielectric layer 38 are bonded together. In the present application, bonding includes bringing two structures into imitate contact with each other and then heating the contact structures such that a bonding interface is formed between the two contacted structures. This bonding interface can be, in some instances, a dielectric-to-dielectric bonding interface.

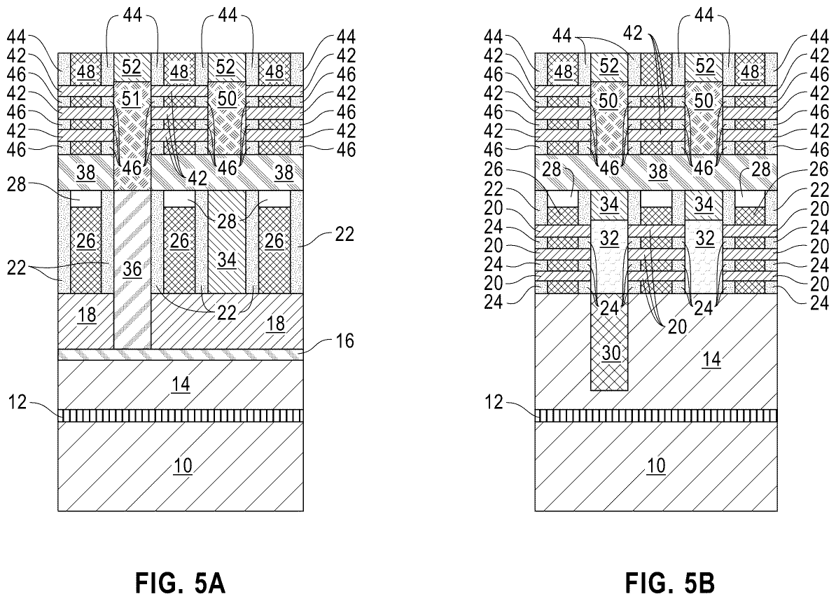

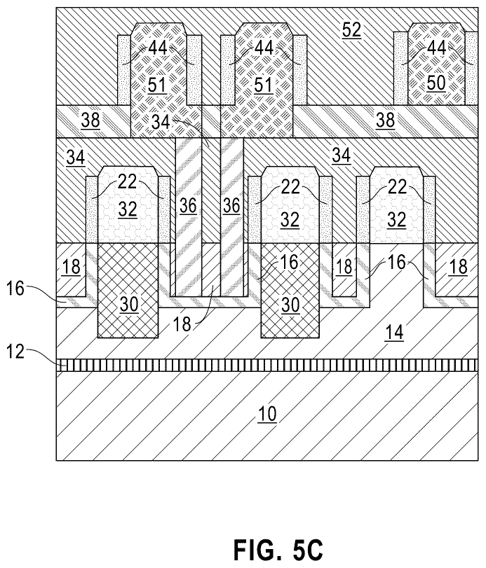

Referring now to FIGS. 5A-5C, there are illustrated the exemplary structure of FIGS. 4A-4C, respectively, after forming a top transistor-containing structure including at least one top transistor (i.e., a top nanosheet transistor) including a top device gate structure 48 and top device source/drain regions (including symmetrical top device source/drain regions 50 and asymmetric top device source/drain regions 51), and a top device first frontside ILD layer 52 embedding the top device source/drain regions, wherein some of the top device source/drain regions (i.e., asymmetric top device source/drain region 51) are formed in contact with an underlying top device source/drain contact placeholder structure 36. The top transistor-containing structure is formed in a top active device area that is shifted relative to the bottom active device area that includes the bottom transition. The shifting is provided by design during the formation of the top transistor-containing structure and the shifting can provide spaced required to allow for wiring of at least one of the asymmetric top device source/drain regions 51 to the backside BEOL structure 74, and for wiring at least one of the bottom device source/drain regions 32 to the frontside BEOL structure 56.

The top transistor-containing structure can also include a top device vertical nanosheet stack of spaced apart top device semiconductor channel material nanosheets 42 (three top device vertical nanosheet stacks are illustrated in the drawings), top device gate spacers 44 located adjacent to the top device gate structure 48 and the top device source/drain regions, and top device inner spacers 46 that are located beneath, and at the ends of each of the top device semiconductor channel material nanosheets 42 in a given top device vertical nanosheet stack. Each of the elements mentioned above for the top transistor-containing structure are now described in greater detail.

The top device semiconductor channel material nanosheets 42 are derived from the top device semiconductor channel material layers 42L of the top device material stack and thus each top device semiconductor channel material nanosheet 42 is composed of the ninth semiconductor material mentioned above.

The top device gate spacers 44 and the top device inner spacers 46 are composed of a same or different dielectric spacer material, as defined above in regard to the bottom device gate spacers 22 and bottom device inner spacers 24.

The top device gate structure 48 includes a top device gate dielectric material and a top device gate electrode, both of which are not separately shown, but intended to be within the region defined by top device gate structure 48. The top device gate dielectric material includes a gate dielectric material such as that described above for the bottom device gate dielectric material. The top device gate dielectric material can be compositionally the same as, or compositionally different from the bottom device gate dielectric material. The top device gate electrode can include a work function metal (WFM) and optionally a conductive metal as defined above for the bottom device gate electrode. The top device gate electrode can be compositionally the same as, or compositionally different from the bottom device gate electrode.

Each top device source/drain region (including symmetrical top device source/drain regions 50 and asymmetric top device source/drain regions 51) is located on opposing sides of a given top device vertical nanosheet stack. Each top device source/drain region (including symmetrical top device source/drain regions 50 and asymmetric top device source/drain regions 51) extends outward from a sidewall of the top device semiconductor channel material nanosheets 42 of a given bottom device vertical nanosheet stack. Each top device source/drain region (including symmetrical top device source/drain regions 50 and asymmetric top device source/drain regions 51) is composed of a tenth semiconductor material and a second dopant. The tenth semiconductor material that provides the top device source/drain regions can be compositionally the same as, or compositionally different from, the ninth semiconductor material that provides each top device semiconductor channel material nanosheet 42. The second dopant that is present in the top device source/drain regions can be of a same conductivity type as, or a different conductivity type, than the first dopant present in the bottom device source/drain regions 32.

The top device frontside ILD layer 52 is composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof.

The exemplary structure shown in FIGS. 5A-5C can be formed utilizing any well-known nanosheet transistor device fabrication process in which the top device material stack is used as an initial material stack The nanosheet transistor device fabrication process typically includes the use of a top device sacrificial gate structure which is used in defining a top device nanosheet stack of alternating top device sacrificial semiconductor nanosheets and top device semiconductor channel material nanosheets 42 from the top device material stack. After defining the top device nanosheet stack, the top device sacrificial gate structure is removed to reveal the underlying top device nanosheet stack and thereafter each top device sacrificial semiconductor material nanosheet of the top device nanosheet stack is removed and thereafter top device gate structure 48 is formed wrapping around each of the suspended top device semiconductor channel material nanosheets 42 of the top device nanosheet stack. The top source/drain regions are then formed. Notably, the asymmetric top device source/drain regions 51 are formed by providing asymmetric top device source/drain region openings that extend through dielectric bonding layer 38 and physically expose the underlying top device source/drain contact placeholder structures 36. Such openings are formed utilizing a bonding dielectric open mask and an etch. The asymmetric top device source/drain regions 51 are formed in each of the asymmetric top device source/drain region openings. The asymmetrical top device source/drain regions 51 are formed by a deposition process such as, for example, CVD, PECVD or epitaxial growth, followed by a recess etch. The bonding dielectric open mask can be removed after forming the asymmetrical top device source/drain regions 51. The symmetrical top device source/drain regions 50 are formed either prior to, or after, forming the asymmetrical top device source/drain regions 51 by a deposition process such as, for example, CVD, PECVD or epitaxial growth, followed by a recess etch. The symmetrical top device source/drain regions 50 are formed on the bonding dielectric layer 38 as shown in FIGS. 5A-5C, in contrast the asymmetrical top device source/drain regions 51 are formed through the bonding dielectric layer as shown in FIGS. 5A and 5C.

The asymmetrical top device source/drain regions 51 are typically L-shaped having a vertical portion that extends upward from a base. The base has a width that is wider than a width of the vertical portion of the asymmetrical top device source/drain regions 51. The symmetrical top device source/drain regions 50 has a substantially constant width throughout the entire of the region. It is noted that the terms “critical dimension” and “width” can be interchangeable used in the present application. The top device first frontside ILD layer 52 is then formed by deposition and planarization. The deposition used in forming the top device first frontside ILD layer 52 can include, for example, CVD, PECVD or spin-on coating

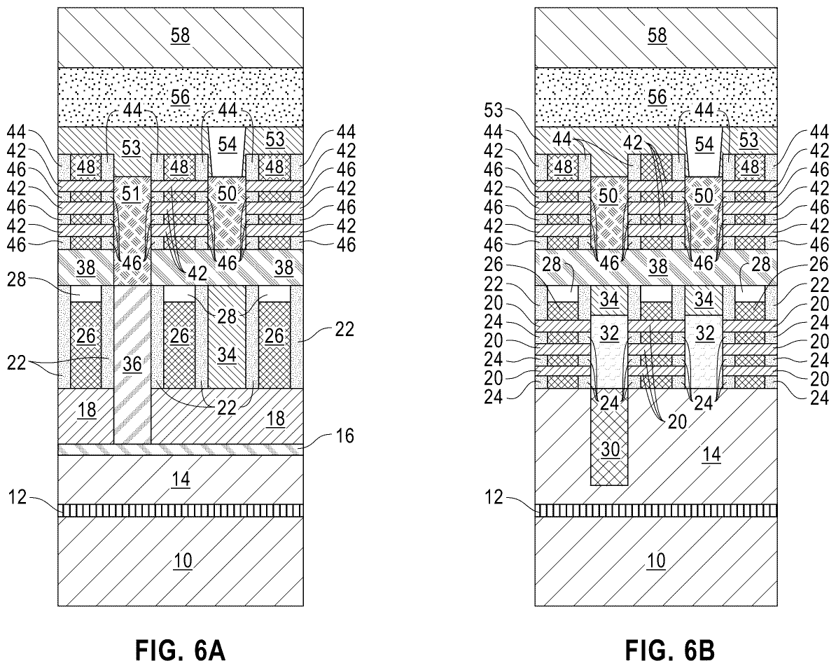

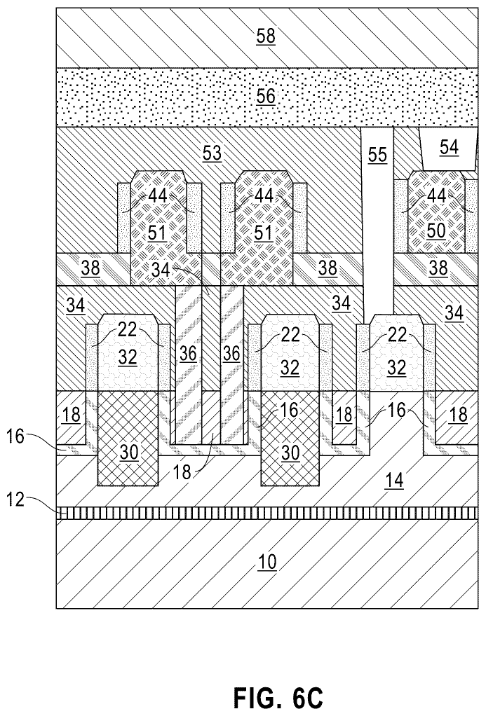

Referring now to FIGS. 6A-6C, there are illustrated the exemplary structure of FIGS. 5A-5C, respectively, after forming a MOL level, a frontside BEOL structure 56 and a carrier wafer 58. The MOL level is formed by first forming a top device second frontside ILD layer (not specifically labeled in FIGS. 6A-6C) on the exemplary semiconductor structure shown in FIGS. 5A-5C. In some areas of the exemplary structure, the top device second frontside ILD layer contacts the top device first frontside ILD layer 52. Collectively, the top device first frontside ILD layer 52 and the top device second frontside ILD layer provide a multi-layered MOL structure 53. The second dielectric layer can be composed of compositionally same, or compositionally different, ILD material than the frontside ILD layer. When the top device first frontside ILD layer 52 and the top device second frontside ILD layer are composed of a compositionally same ILD material, no material interface is present between the two ILD layers (such an embodiment in illustrated in FIGS. 6A-6C). When the top device first frontside ILD layer 52 and the top device second frontside ILD layer are composed of compositionally different ILD materials, a material interface (not shown) is present between the two ILD layers. The top device second frontside ILD layer can be formed by a deposition process, followed by a planarization process.

The MOL level formation continues by forming various frontside contact structures including a top device frontside source/drain contact structure 54 (two of which are shown by way of one example), and a bottom device frontside contact source/drain structure 55. In the present application, each top device frontside contact source/drain contact structure 54 contacts one of the top device source/drain regions 50, while the bottom device frontside contact source/drain structure 55 contacts one of the bottom device source/drain regions 32. Each of the frontside contact structures is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. Each of frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. Each of the frontside contact structures can be formed by a metallization process which includes forming (by lithography and etching) frontside contact openings in at least some of the ILD layers that provide the MOL multi-layered structure 53, and then filling each frontside contact opening with at least a contact conductor material as defined above. The filling of each frontside contact opening can include a deposition process (such as, for example, CVD, PECVD, atomic layer deposition (ALD) or sputtering), followed by a planarization process.

The frontside BEOL structure 56 is formed on top of the MOL level. The frontside BEOL structure 56 is composed of an interconnect dielectric region having frontside metal wiring embedded therein. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. The frontside BEOL structure 56 can be formed utilizing any well-known BEOL process including a damascene process or a subtractive metal etch process. It is noted that the frontside BEOL structure 56 is electrically connected to each of the transistors through the frontside contact structures described above (notably by each top device frontside source/drain contact structure 54 and each bottom device frontside contact source/drain structure 55).

After forming the frontside BEOL structure 56, carrier wafer 58 is formed on the frontside BEOL structure 56. Carrier wafer 58 can include a semiconductor material as defined above. Carrier wafer 58 is bonded to the frontside BEOL structure 56 utilizing any bonding process that is well known to those skilled in the art. This concludes the frontside processing of the exemplary structure, backside processing will now be performed.

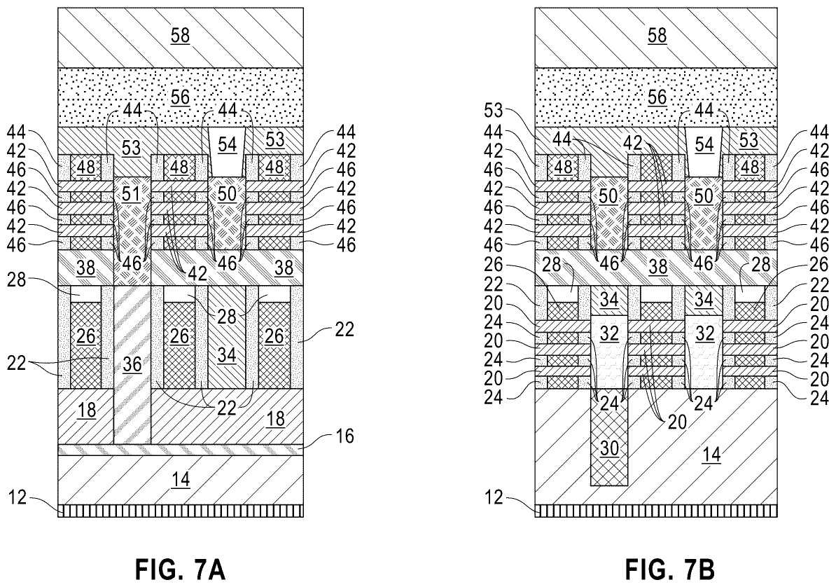

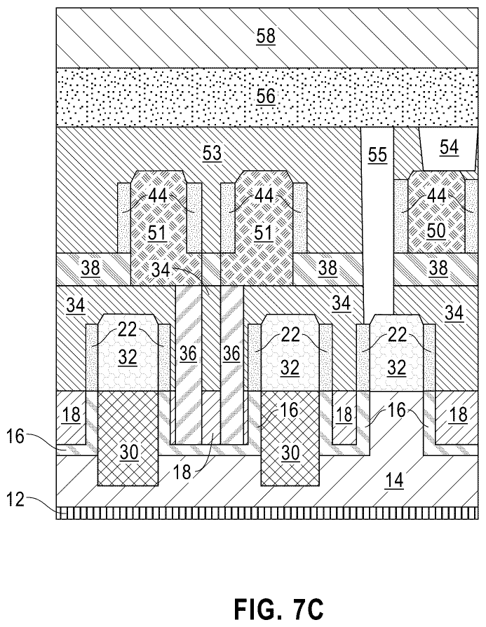

Referring now to FIGS. 7A-7C, there are illustrated the exemplary structure of FIGS. 6A-6C, respectively, after wafer flipping and removing semiconductor base layer 10 of the substrate. In the present application, backside processing begins by flipping the exemplary structure 180° to physically expose a backside of the structure. For clarity, the flipping step is not shown in the drawings. Flipping can be performed by hand or by utilizing a mechanical means such as, for example, a robot arm. After flipping, and in the illustrated embodiment, the semiconductor base layer 10 is physically exposed and the physically exposed semiconductor base layer 10 is removed utilizing a material removal process that is selective in removing the semiconductor material that provides the semiconductor base layer 10. The removal of the semiconductor base layer 10 reveals the etch stop layer 12. The removal of the semiconductor base layer 10 can be omitted when no semiconductor base layer 10 is present in the substrate.

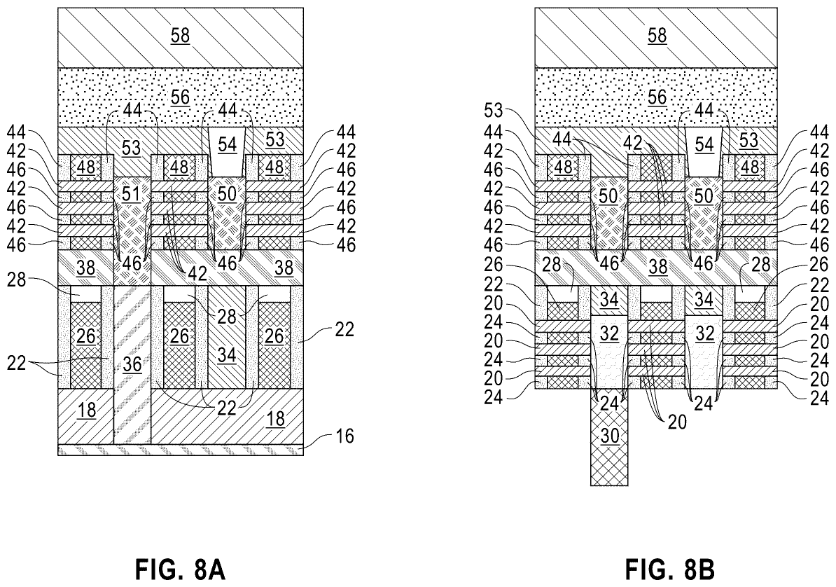

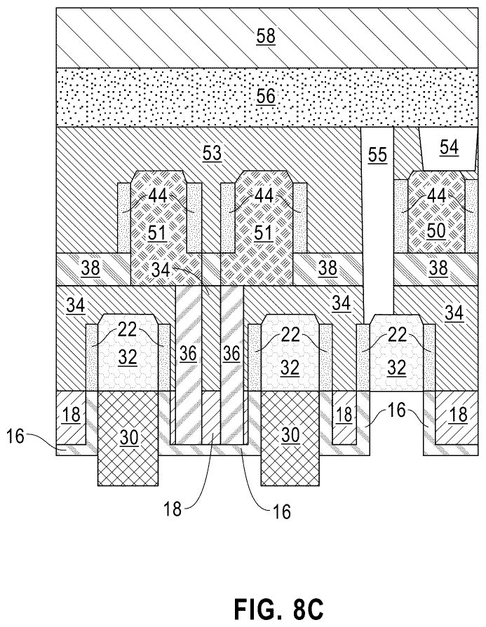

Referring now to FIGS. 8A-8C, there are illustrated the exemplary structure of FIGS. 7A-7C, respectively, after removing etch stop layer 12 and semiconductor device layer 14 of the substrate to reveal the bottom device backside source/drain contact placeholder structures 30 and the trench dielectric liner 16 of the shallow trench isolation structure. The etch stop layer 12 can be removed utilizing a material removal process that is selective in removing the material that provides the etch stop layer 12. The removal of the etch stop layer 12 physically exposes the semiconductor device layer 14. It is noted that the removal of the etch stop layer 12 can be omitted when such a layer is not present. The semiconductor device layer 14 can be removed utilizing a material removal process that is selective in removing the semiconductor device layer 14.

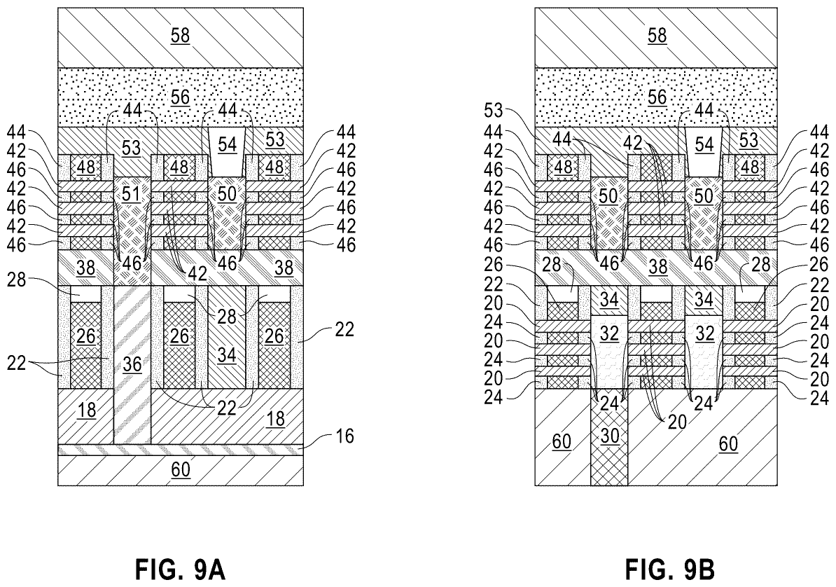

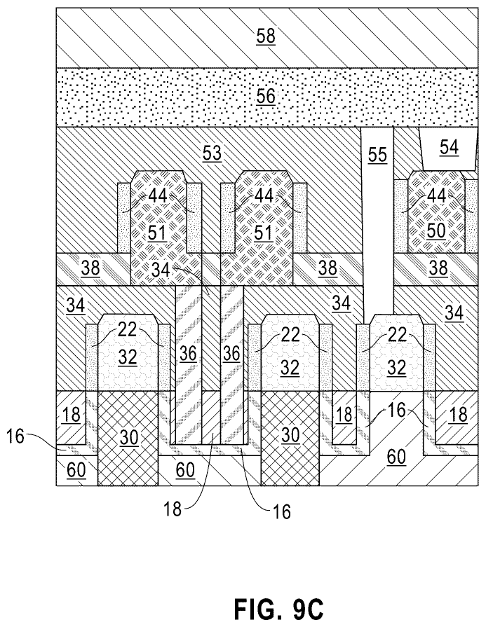

Referring now to FIGS. 9A-9C, there are illustrated the exemplary structure of FIGS. 8A-8C, respectively, after forming a first backside ILD layer 60 contacting the trench dielectric liner 16 and embedding the bottom device backside source/drain contact placeholder structures 30. The first backside ILD layer 60 is composed of an ILD material as mentioned above for the bottom device frontside ILD layer 34. The first backside ILD layer 60 can be formed by a deposition process (e.g., CVD, PECVD or spin-on coating), followed by a planarization process. After planarization, the first backside ILD layer 60 has a bottommost surface (as shown in FIGS. 9B and 9C) that is substantially coplanar with a bottommost surface of the bottom device backside source/drain contact placeholder structures 30.

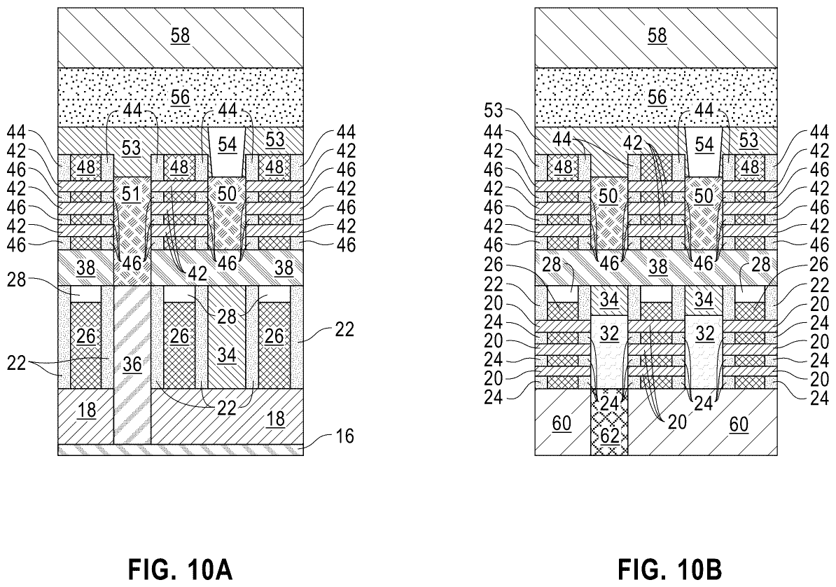

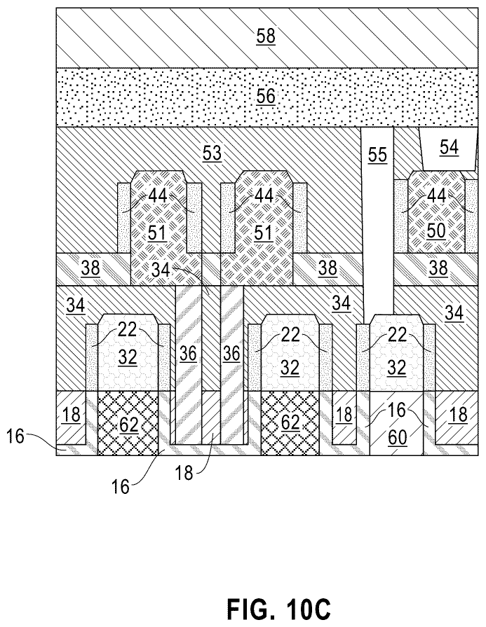

Referring now to FIGS. 10A-10C, there are illustrated the exemplary structure of FIGS. 9A-9C, respectively, after replacing the bottom device backside source/drain contact placeholder structures 30 with bottom device backside source/drain contact structures 62. The replacing of the bottom device backside source/drain contact placeholder structures 30 includes a material removal process (e.g., RIE) that is selective in removing the bottom device backside source/drain contact placeholder structures 30. In some embodiments in which a semiconductor buffer layer is present, the etch can also remove the semiconductor buffer layer. The removal of the bottom device backside source/drain contact placeholder structures 30 (and if present, the semiconductor buffer layer) reveals the bottom device source/drain regions 32 as shown in FIGS. 10B-10C. After revealing the bottom device source/drain regions 32, bottom device backside source/drain contact structures 62 are formed. The bottom device backside source/drain contact structures 62 are composed of at least a contact conductor material, as defined above, and can include any of the liners/diffusion barriers mentioned above for the frontside contact structures. The bottom device backside source/drain contact structures 62 can be formed by deposition, followed by a planarization process. The bottom device backside source/drain contact structures 62 are self-aligned contact structures since no separate masking layer or lithographic step are used in forming the same. As illustrated in FIG. 10C, each bottom device backside source/drain contact structures 62 is formed between trench dielectric liners 16 of adjacent shallow trench isolation structures.

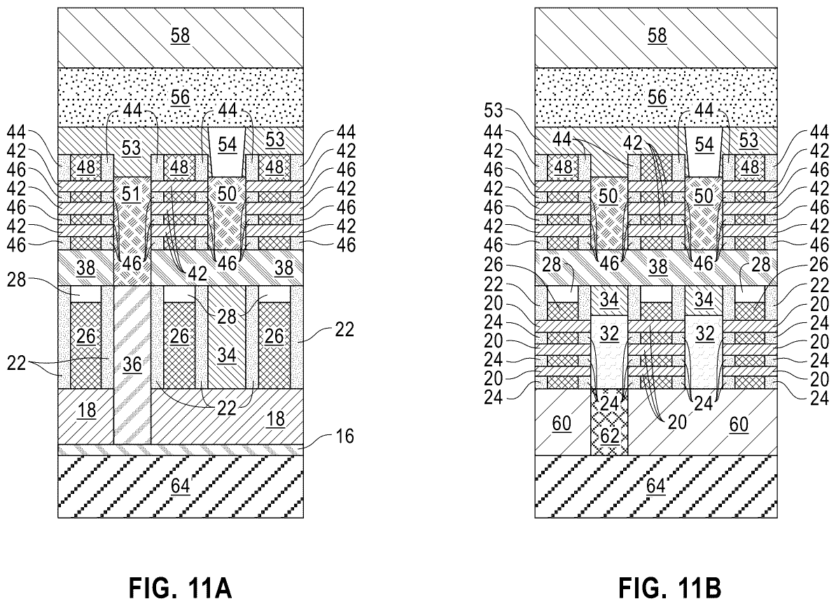

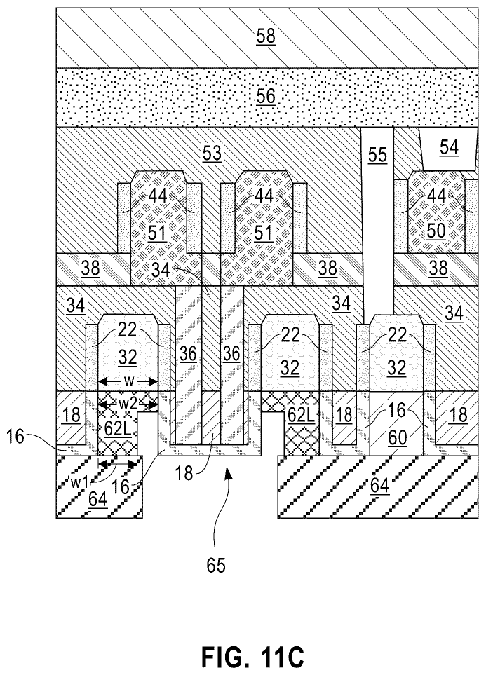

Referring now to FIGS. 11A-11C, there are illustrated the exemplary structure of FIGS. 10A-10C, respectively, after asymmetric backside contact patterning in which the bottom device backside source/drain contact structures 62 are patterned into asymmetrical bottom device backside source/drain contact structures 62L. Each asymmetrical bottom device backside source/drain contact structure 62L has an inverted L shape as shown in FIG. 11C that includes a vertical portion of a first width, w1, and a horizontal portion extending outward from the vertical portion that has a second width, w2, in which w2 is greater than w1 and the horizontal portion is in contact with one (i.e., a first bottom device source/drain region) of the bottom device source/drain regions 32. The second width, w2, of the vertical portion of the asymmetrical bottom device backside source/drain contact structures 62L is equal to a width, w, of a bottom portion of this first bottom device source/drain region such that the asymmetrical bottom device backside source/drain contact structures 62L covers (i.e., contacts) an entirety of the first bottom device source/drain region.

The asymmetric backside contact patterning begins with first forming a patterned masking layer 64 having an opening 65 formed thereon. The opening 65 is located beneath the top device source/drain contact placeholder structures 36 that are located adjacent to the bottom device source/drain regions 32 and is designed to physically expose a portion of the bottom device backside source/drain regions 32 (See, for example, FIG. 11C). The patterned masking layer 64 is composed of a masking material or a combination of masking materials that are well known to those skilled in the art. In one example, the masking material that provides the patterned masking layer 64 is an organic planarization material. The patterned masking layer 64 can be formed by deposition of the masking material(s), followed by lithographic patterning. The asymmetric backside contact patterning continues by etching (e.g., RIE) the physically exposed portion of the bottom device backside source/drain contacts 32 to provide the asymmetrical bottom device backside source/drain contact structures 62L. After providing the asymmetrical bottom device backside source/drain contact structures 62L, the patterned masking layer 64 can be removed from the structure utilizing a material removal process such as, for example, ashing, which is selective in removing the patterned masking layer 64.

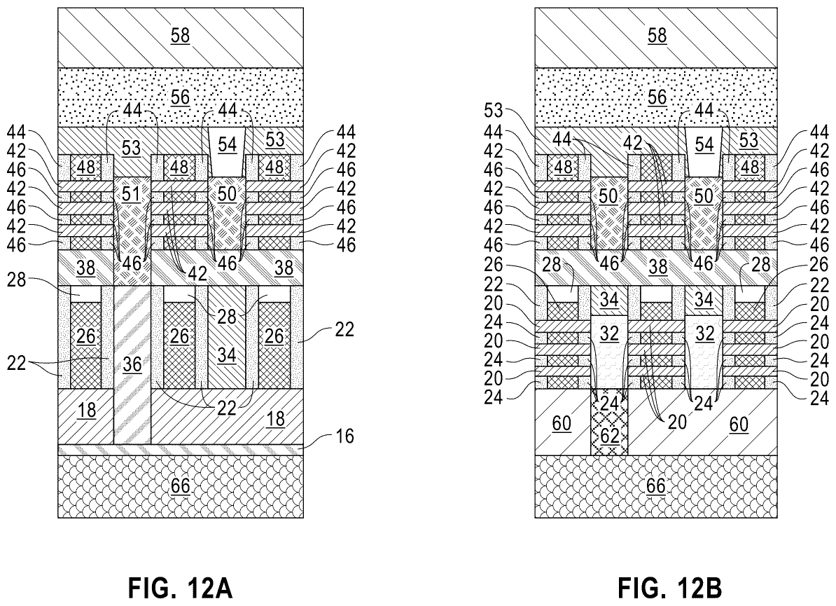

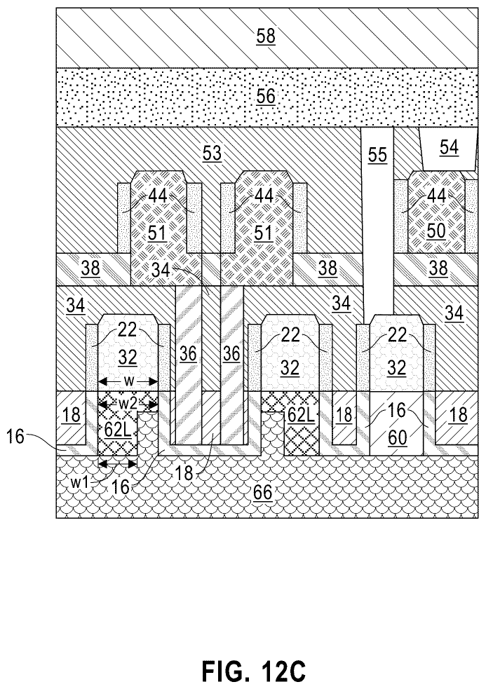

Referring now to FIGS. 12A-12C, there are illustrated the exemplary structure of FIGS. 11A-11C, respectively, after forming a second backside ILD layer 66. The second backside ILD layer 66 is composed of an ILD material as mentioned above for the bottom device frontside ILD layer 34. The second backside ILD layer 66 can be composed of a compositionally same, or a compositionally different, ILD material than the first backside ILD layer 60. The second backside ILD layer 66 can be formed by a deposition process (e.g., CVD, PECVD or spin-on coating), followed by a planarization process.

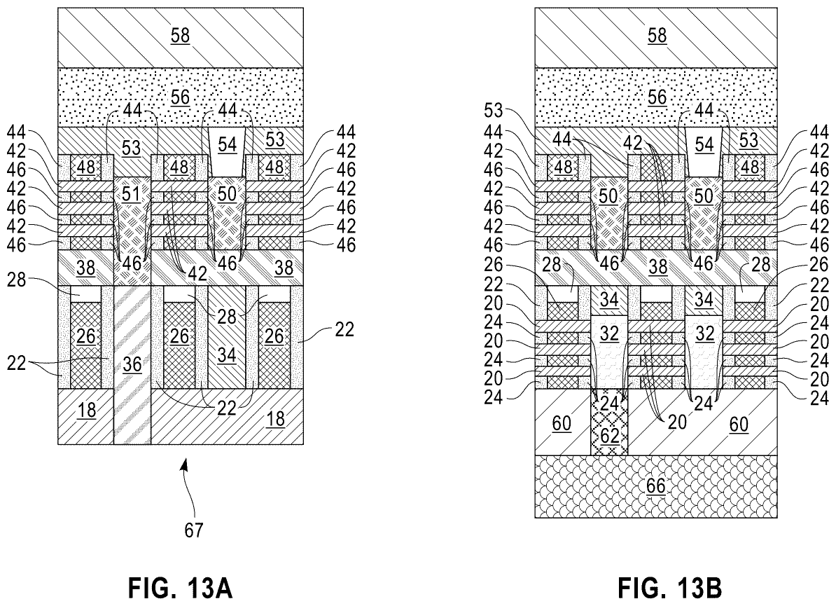

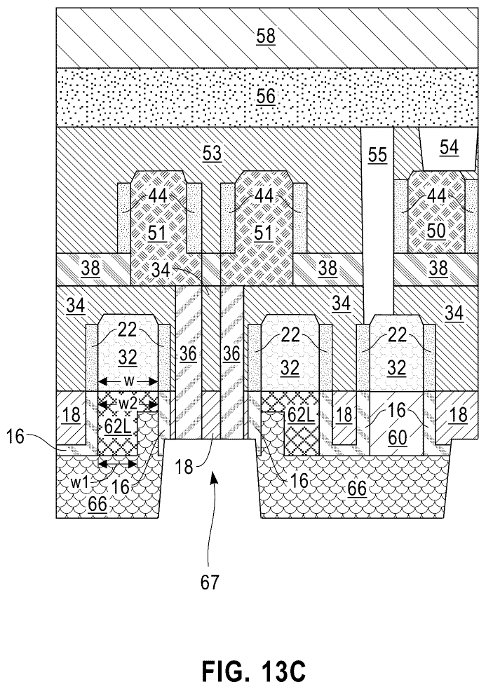

Referring now to FIGS. 13A-13C, there are illustrated the exemplary structure of FIGS. 12A-12C, respectively, after VDD backside power rail patterning in which the top device source/drain contact placeholder structures 36 are revealed. Also revealed by the VDD backside power rail patterning is the trench dielectric material 18 of the shallow trench isolation structure (See, for example, FIGS. 13A and 13C). The VDD backside power rail patterning includes lithography patterning as defined above. In the present application, the etch used in the pattern transfer is selective in removing a physically exposed portion of the second backside ILD layer 66 and portion of the trench dielectric liner 16 such that the top device source/drain contact placeholder structures 36 and the trench dielectric material 18 of the shallow trench isolation structure are both revealed. Openings 67 are formed in this step of the present application.

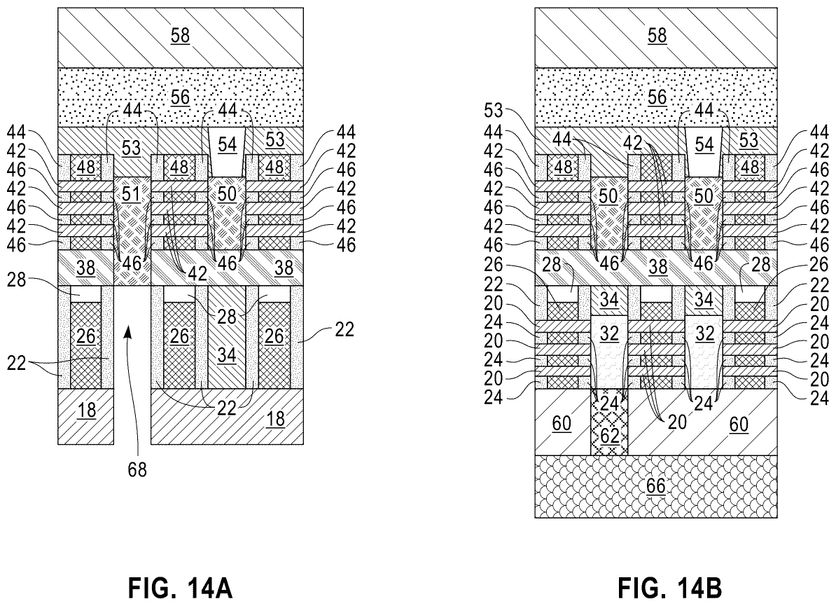

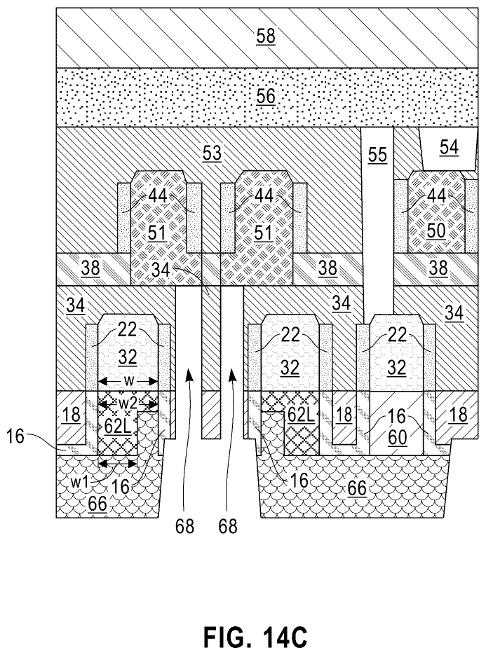

Referring now to FIGS. 14A-14C, there are illustrated the exemplary structure of FIGS. 13A-13C, respectively, after removing the top device source/drain contact placeholder structures 36. The top device source/drain contact placeholder structures 36 can be removed utilizing a material removal process such as, for example, RIE, that is selective in removing the top device source/drain contact placeholder structures 36. The removal of the top device source/drain contact placeholder structures 36 forms top device backside source/drain contact openings 68. Each top device backside contact opening 68 physically exposes one of the asymmetric top device source/drain regions 51 as is illustrated in FIGS. 14A and 14C.

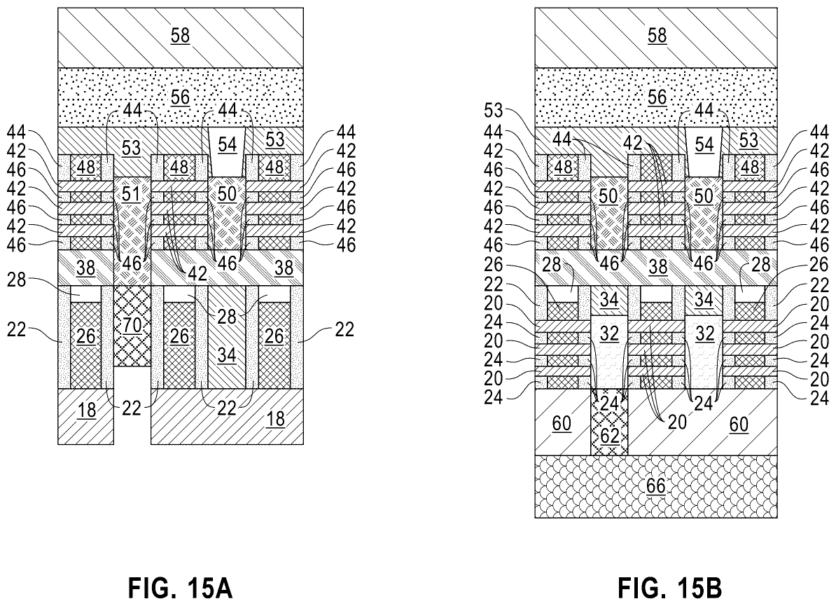

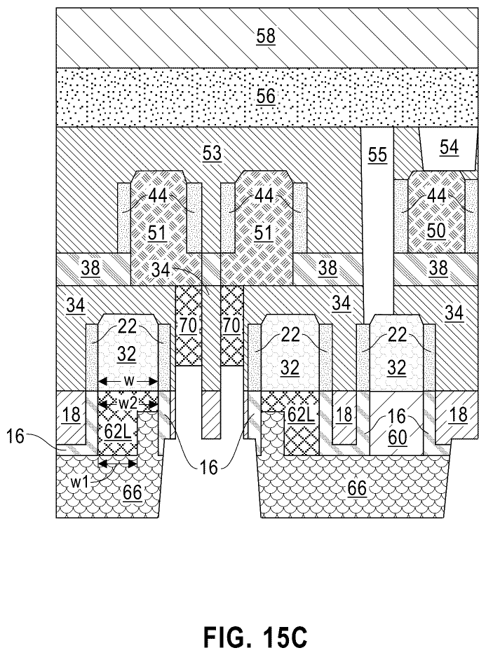

Referring now to FIGS. 15A-15C, there are illustrated the exemplary structure of FIGS. 14A-14C, respectively, after forming top device backside source/drain contact structures 70. Each top device backside source/drain contact structure 70 is formed in an upper portion of one of the top device backside source/drain contact openings 68 and is in direct contact with one of the asymmetric top device source/drain regions 51. Each top device backside source/drain contact structure 70 is composed of at least a contact conductor material, as defined above, and can include any of the liners/diffusion barriers mentioned above for the frontside contact structures. The top device backside source/drain contact structures 70 can be formed by deposition, followed by a planarization process. The top device backside source/drain contact structures 70 are self-aligned contact structures since no separate masking layer or lithographic step are used in forming the same.

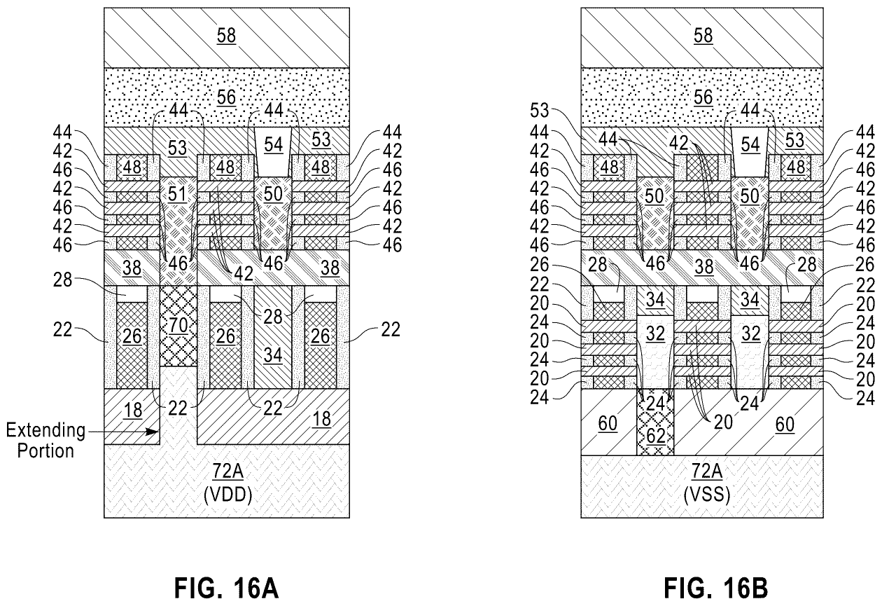

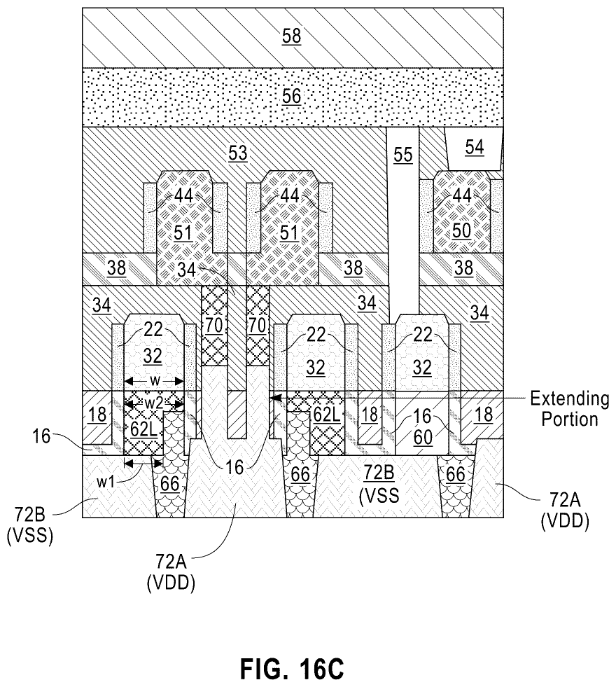

Referring now to FIGS. 16A-16C, there are illustrated the exemplary structure of FIGS. 15A-15C, respectively, after VSS backside power rail patterning and VDD/VSS backside power rail metallization. The VSS backside power rail patterning including lithographic patterning as defined above. The VDD/VSS backside power rail metallization includes deposition of an electrically conductive power rail material, followed by planarization. The electrically conductive power rail material includes, but is not limited to, W, Co, Ru, Al, Cu, Pt, Rh, or Pd. The VDD/VSS backside power rail metallization forms VDD backside power rails 72A and VDD backside power rails 72B. A thin metal adhesion layer, such as TiN, TaN, etc. can be also formed along a sidewall and bottom wall of the VDD backside power rails 72A and/or VSS backside power rails 72B. In FIGS. 16A-16C, the terms “VDD” and “VSS” are shown in parentheses. VDD stands for a positive supply voltage, while VSS stands for a ground or reference voltage. The designations are included in the drawings to show the location of these different volage levels.

In the present application, each VDD backside power rail 72A is electrically connected to the asymmetric top device source/drain regions 51 by means of one of the top device backside source/drain contact structures 70, while each VSS backside power rail 72B is electrically connected to a bottom device source/drain region 32 by means of one of the asymmetric bottom device backside source/drain contact structures 62L. The VDD backside power rails 72A have a vertical portion that extends from a backside of the device to a frontside of the device as shown in FIGS. 16A-16C. The vertical portion of the VDD backside power rail 72A that extends from the backside of the device to the frontside of the device has a same width as that of top device backside source/drain contact structures 70. It is noted that the asymmetric bottom device backside source/drain contact structures 62L has a notch that prevents the asymmetric bottom device backside source/drain contact structures 62L from contacting an adjacent VDD backside power rail 72A and hence shorting of the device is avoided.

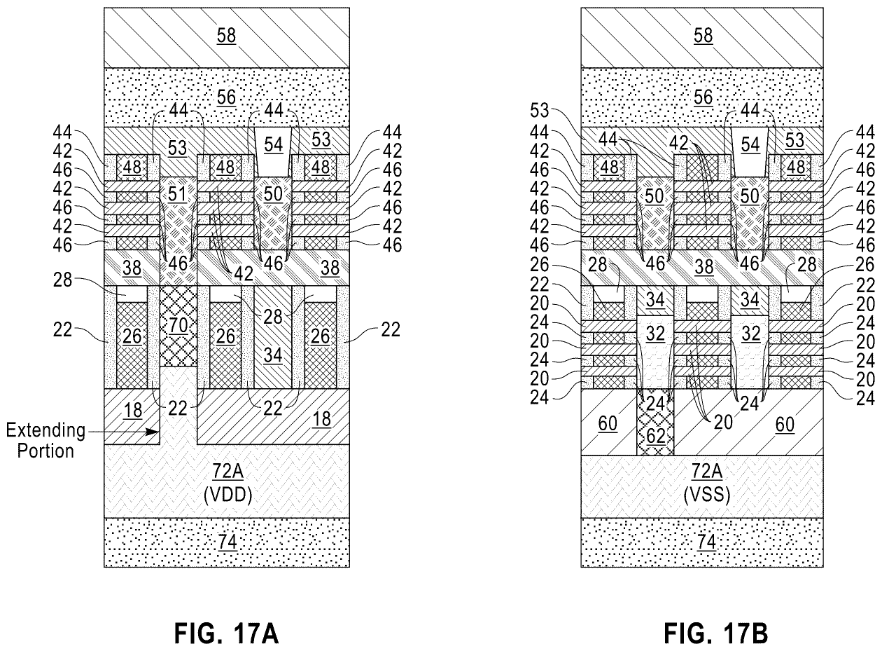

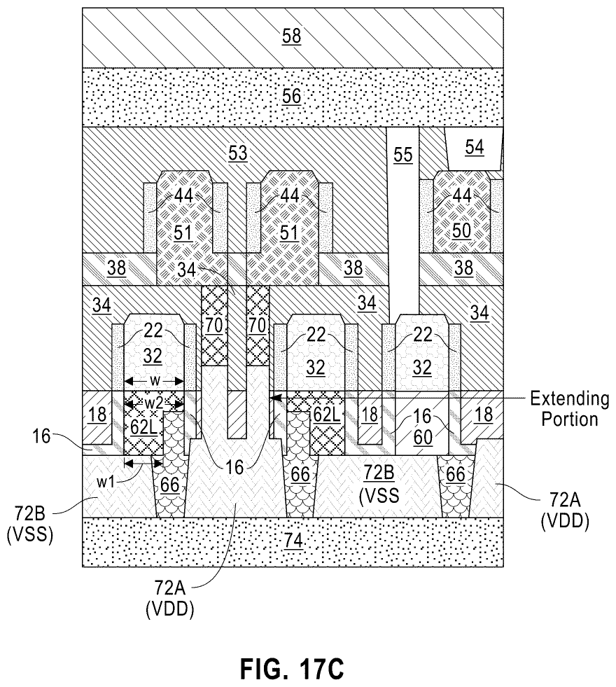

Referring now to FIGS. 17A-17C, there are illustrated the exemplary structure of FIGS. 16A-16C, respectively, after forming a backside BEOL structure 74. The backside BEOL structure 74 (which can delivery power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 74 can be formed utilizing any well-known BEOL process including a damascene process or a subtractive metal etch process.

In the present application, the backside BEOL structure 74 is electrically connected to the asymmetric top device source/drain regions 51 by means of the VDD backside power rail 72A and one of the top device backside source/drain contact structures 70. The backside BEOL structure 74 is also electrically connected to the bottom device source/drain regions 32 by means of the VSS backside power rail 72B and one of the asymmetric bottom device backside source/drain contact structures 62L.

Notably, FIGS. 17A-17C illustrate a semiconductor device in accordance with one embodiment of the present application. The semiconductor device incudes a bottom transistor including bottom device gate structure 26 and bottom device source/drain regions 32 located in a bottom active device area, a top transistor stacked above the bottom transistor and including top device gate structure 48 and top device source/drain regions (i.e., symmetrical top device source/drain region 50 and asymmetric top device source/drain region 51) located in a top active device area, in which the top active device area is shifted relative to the bottom active device area (see, for example, FIG. 1), backside BEOL structure 74 located beneath the bottom transistor, asymmetrical bottom device backside source/drain contact structure 62L electrically connecting a first bottom device source/drain region of the bottom device source/drain regions 32 to the backside BEOL structure 74, and top device backside source/drain contact structure 70 electrically connecting a first top device source/drain region of the top device source/drain regions (i.e., asymmetric top device source/drain region 51) to the backside BEOL structure 74. The asymmetric shape of the asymmetrical bottom device backside source/drain contact structure 62L maximizes the contact area between the asymmetrical bottom device backside source/drain contact structure 62L and the first bottom device source/drain region, while avoiding shorting to the neighboring VDD backside power rail 72A by removing the bottom metal portion nearby.

In embodiments of the present application, the semiconductor device can further include VSS backside power rail 72B located between, and in contact with, the asymmetrical bottom device backside source/drain contact structure 62L and the backside BEOL structure 74. The asymmetric shape of the asymmetrical bottom device backside source/drain contact structure 62L ensures good connection between the asymmetrical bottom device backside source/drain contact structure 62L and the VSS backside power rail 72B, without a shorting risk to the neighboring VDD backside power rail 72A.

In embodiments of the present application, the semiconductor device can further include VDD backside power rail 72A located between, and in contact with, the top device backside source/drain contact structure 70 and the backside BEOL structure 74.

In some embodiments of the present application, the VDD backside power rail 72A has a vertical portion that extends from a backside of the device to a frontside of the device. This allows for a lower vertical resistance because the VDD backside power rail 72A is composed of a conductive material that has a lower resistance than the material that provides the top device backside source/drain contact structure 70.

In embodiments of the present application, the asymmetrical bottom device backside source/drain contact structure 62L has an inverted L shape including a vertical portion of a first width, w1, and a horizontal portion extending outward from the vertical portion that has a second width, w2, in which w2 is greater than w1, and the horizontal portion is in contact with the first bottom device source/drain region, and w2 of the vertical portion of the asymmetrical bottom device backside source/drain contact structure 62L is equal to a width, w, of a bottom portion of the first bottom device source/drain region. The aspect that w2 equals w ensures that asymmetrical bottom device backside source/drain contact structure 62L covers (i.e., contacts) an entirety of a bottommost surface of the first bottom device source/drain region. The aspect that w2 is greater than w1 ensures that the asymmetrical bottom device backside source/drain contact structure 62L does not contact VDD backside power rail 72A and thus shorting is avoided.

In some embodiments of the present application, the first top device source/drain region that is electrically connected to the backside BEOL structure 74 is an asymmetric top device source/drain region 51 having a vertical portion that extends upward from a base, wherein the base has a width that is wider than a width of the vertical portion. This allows for a robust connection between the top device backside source/drain contact structure 70 and the asymmetric top device source/drain region 51.

In some embodiments of the present application, the semiconductor device further includes frontside BEOL structure 56 located above the top transistor.

In some embodiments of the present application, the semiconductor device further includes bottom device frontside source/drain structure 55 electrically connecting the frontside BEOL structure 56 to a second bottom device source/drain region of the bottom device source/drain regions 32.

In some embodiments of the present application, the semiconductor device further includes top device frontside source/drain structure 54 electrically connecting the frontside BEOL structure 56 to a second top device source/drain region of the top device source/drain regions (i.e., the symmetrical top source/drain region 50).

In some embodiments of the present application, the semiconductor device further includes bonding dielectric layer 38 located between the bottom transistor and the top transistor, in which the first top device source/drain region (i.e., asymmetric top device source/drain region 51) that is electrically connected to backside BEOL structure 74 extends into the bonding dielectric layer 38.

In another embodiment of the present application and as shown in FIGS. 17A-17C, the semiconductor device includes a bottom transistor including bottom device gate structure 26 and bottom device source/drain regions 32 located in a bottom active device area, a top transistor stacked above the bottom transistor and including top device gate structure 48 and top device source/drain regions (i.e., symmetrical top device source/drain region 50 and asymmetric top device source/drain region 51) located in a top active device area, in which the top active device area is shifted relative to the bottom active device area (see, for example, FIG. 1), backside BEOL structure 74 located beneath the bottom transistor, asymmetrical bottom device backside source/drain contact structure 62L having a horizontal portion contacting an entirety of a bottommost surface of a first bottom device source/drain region of the bottom device source/drain regions 32 of the bottom transistor and a vertical portion contacting the backside BEOL structure 74, and top device backside source/drain contact structure 70 electrically connecting a first top device source/drain region (i.e., asymmetric top device source/drain region 51) of the top device source/drain regions to the backside BEOL structure 74. The asymmetric shape of the asymmetrical bottom device backside source/drain contact structure 62L maximizes the contact area between the asymmetrical bottom device backside source/drain contact structure 62L and the first bottom device source/drain region, while avoiding shorting to the neighboring VDD backside power rail 72A by removing the bottom metal portion nearby.

In embodiments of the present application, the semiconductor device can further include VSS backside power rail 72B located between, and in contact with, the asymmetrical bottom device backside source/drain contact structure 62L and the backside BEOL structure 74. The asymmetric shape of the asymmetrical bottom device backside source/drain contact structure 62L ensures good connection between the asymmetrical bottom device backside source/drain contact structure 62L and the VSS backside power rail 72B, without a shorting risk to the neighboring VDD backside power rail 72A.

In embodiments of the present application, the semiconductor device can further include VDD backside power rail 72A located between, and in contact with, the top device backside source/drain contact structure 70 and the backside BEOL structure 74.

In some embodiments of the present application, the VDD backside power rail 72A has a vertical portion that extends from a backside of the device to a frontside of the device. This allows for a lower vertical resistance because the VDD backside power rail 72A is composed of a conductive material that has a lower resistance than the material that provides the top device backside source/drain contact structure 70.

In embodiments of the present application, the vertical portion of the asymmetrical bottom device backside source/drain contact structure 62L has a first width, w1, and the horizontal portion of the asymmetrical bottom device backside source/drain contact structure 62L has a second width, w2, in which w2 is greater than w1, and w2 of the vertical portion of the asymmetrical bottom device backside source/drain contact structure 62L is equal to a width, w, of a bottom portion of the first bottom device source/drain region. The aspect that w2 equals w ensures that asymmetrical bottom device backside source/drain contact structure 62L covers an entirety of a bottommost surface of the first bottom device source/drain region. The aspect that w2 is greater than w1 ensures that the asymmetrical bottom device backside source/drain contact structure 62L does not contact VDD backside power rail 72A and thus shorting is avoided.

In some embodiments of the present application, the first top device source/drain region that is electrically connected to the backside BEOL structure 74 is an asymmetric top device source/drain region 51. The asymmetric shape provides for greater surface area for backside contact formation.

In some embodiments of the present application, the semiconductor device further includes frontside BEOL structure 56 located above the top transistor.

In some embodiments of the present application, the semiconductor device further includes bottom device frontside source/drain structure 55 electrically connecting the frontside BEOL structure 56 to a second bottom device source/drain region of the bottom device source/drain regions 32.

In some embodiments of the present application, the semiconductor device further includes top device frontside source/drain structure 54 electrically connecting the frontside BEOL structure 56 to a second top device source/drain region (i.e., the symmetrical top source/drain region 50) of the top device source/drain regions.

In some embodiments of the present application, the semiconductor device further includes bonding dielectric layer 38 located between the bottom transistor and the top transistor, in which the first top device source/drain region (i.e., asymmetric top device source/drain region 51) that is electrically connected to backside BEOL structure 74 extends into the bonding dielectric layer 38.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a bottom transistor comprising a bottom device gate structure and bottom device source/drain regions located in a bottom active device area;
a top transistor stacked above the bottom transistor and comprising a top device gate structure and top device source/drain regions located in a top active device area, wherein the top active device area is shifted relative to the bottom active device area;
a backside back-end-of-the-line (BEOL) structure located beneath the bottom transistor;
an asymmetrical bottom device backside source/drain contact structure electrically connecting to a first bottom device source/drain region of the bottom device source/drain regions to the backside BEOL structure; and
a top device backside source/drain contact structure electrically connecting a first top device source/drain region of the top device source/drain regions to the backside BEOL structure.

2. The semiconductor device of claim 1, further comprising a VSS backside power rail located between, and in contact with, the asymmetrical bottom device backside source/drain contact structure and the backside BEOL structure.

3. The semiconductor device of claim 1, further comprising a VDD backside power rail located between, and in contact with, the top device backside source/drain contact structure and the backside BEOL structure.

4. The semiconductor device of claim 3, wherein the VDD backside power rail has a vertical portion that extends from a backside of the semiconductor device to a frontside of the semiconductor device.

5. The semiconductor device of claim 1, wherein the asymmetrical bottom device backside source/drain contact structure has an inverted L shape comprising a vertical portion of a first width and a horizontal portion extending outward from the vertical portion that has a second width, wherein the second width is greater than the first width, and the horizontal portion is in contact with the first bottom device source/drain region, and the second width of the vertical portion of the asymmetrical bottom device backside source/drain contact structure is equal to a width of a bottom portion of the first bottom device source/drain region.

6. The semiconductor device of claim 1, wherein the first top device source/drain region that is electrically connected to the backside BEOL structure is an asymmetric top device source/drain region having a vertical portion that extends upward from a base, wherein the base has a width that is wider than a width of the vertical portion.

7. The semiconductor device of claim 1, further comprising a frontside BEOL structure located above the top transistor.

8. The semiconductor device of claim 7, further comprising a bottom device frontside source/drain structure electrically connecting the frontside BEOL structure to a second bottom device source/drain region of the bottom device source/drain regions.

9. The semiconductor device of claim 7, further comprising a top device frontside source/drain structure electrically connecting the frontside BEOL structure to a second top device source/drain region of the top device source/drain regions.

10. The semiconductor device of claim 1, further comprising a bonding dielectric layer located between the bottom transistor and the top transistor, wherein the first top device source/drain region that is electrically connected to backside BEOL structure extends into the bonding dielectric layer.

11. A semiconductor device comprising:
a bottom transistor comprising a bottom device gate structure and bottom device source/drain regions located in a bottom active device area;
a top transistor stacked above the bottom transistor and comprising a top device gate structure and top device source/drain regions located in a top active device area, wherein the top active device area is shifted relative to the bottom active device area;
a backside back-end-of-the-line (BEOL) structure located beneath the bottom transistor;
an asymmetrical bottom device backside source/drain contact structure having a horizontal portion contacting an entirety of a bottommost surface of a first bottom device source/drain region of the bottom device source/drain regions and a vertical portion contacting the backside BEOL structure; and
a top device backside source/drain contact structure electrically connecting a first top device source/drain region of the top device source/drain regions to the backside BEOL structure.

12. The semiconductor device of claim 11, further comprising a VSS backside power rail located between, and in contact with, the asymmetrical bottom device backside source/drain contact structure and the backside BEOL structure.

13. The semiconductor device of claim 11, further comprising a VDD backside power rail located between, and in contact with, the top device backside source/drain contact structure and the backside BEOL structure.

14. The semiconductor device of claim 13, wherein the VDD backside power rail has a vertical portion that extends from a backside of the semiconductor device to a frontside of the semiconductor device.

15. The semiconductor device of claim 11, wherein the vertical portion of the asymmetrical bottom device backside source/drain contact structure has a first width and the horizontal portion of the asymmetrical bottom device backside source/drain contact structure has a second width, wherein the second width is greater than the first width, and the second width of the vertical portion of the asymmetrical bottom device backside source/drain contact structure is equal to a width of a bottom portion of the first bottom device source/drain region.

16. The semiconductor device of claim 11, wherein the first top device source/drain region that is electrically connected to the backside BEOL structure is an asymmetric top device source/drain region.

17. The semiconductor device of claim 11, further comprising a frontside BEOL structure located above the top transistor.

18. The semiconductor device of claim 17, further comprising a bottom device frontside source/drain structure electrically connecting the frontside BEOL structure to a second bottom device source/drain region of the bottom device source/drain regions.

19. The semiconductor device of claim 17, further comprising a top device frontside source/drain structure electrically connecting the frontside BEOL structure to a second top device source/drain region of the top device source/drain regions.

20. The semiconductor device of claim 11, further comprising a bonding dielectric layer located between the bottom transistor and the top transistor, wherein the first top device source/drain region that is electrically connected to backside BEOL structure extends into the bonding dielectric layer.
